(19) United States
(12) Patent Application Publication
(10) Pub. No.: US 2009/0233189 A1
(43) Pub. Date: Sep. 17, 2009

(54) DEVICE AND METHOD FOR OBTAINING EXPOSURE CORRECTION INFORMATION, AND MANUFACTURING METHOD OF SEMICONDUCTOR DEVICE

(76) Inventors: Kazuya FUKUHARA, Tokyo (JP); Satoshi TANAKA, Kanagawa (JP); Masamitsu ITOH, Kanagawa (JP); Soichi INOUE, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/401,840

(22) Filed: Mar. 11, 2009

(30) Foreign Application Priority Data
Mar. 12, 2008 (JP) 2008-063343

(51) Int. Cl. G03F 1/00; G03B 27/54; G03F 7/20

(52) U.S. Cl. 430/5; 355/67; 430/30

(57) ABSTRACT

A method of obtaining exposure correction information includes adjusting intensity of light incident on a photomask so that intensity of light output from the photomask has a desired distribution, and includes obtaining the exposure correction information as a distribution of the adjusted intensity of light incident on the photomask.

### CROSS-REFERENCE TO RELATED APPLICATIONS

This application is based upon and claims the benefit of priority from the prior Japanese Patent Application No. 2008-63343, filed on Mar. 12, 2008; the entire contents of which are incorporated herein by reference.

### BACKGROUND OF THE INVENTION

1. Field of the Invention

The present invention relates to a device that obtains exposure correction information and a method of obtaining exposure correction information. And the present invention relates to a method of manufacturing a semiconductor device too.

2. Description of the Related Art

Along with progress of techniques of manufacturing semiconductor devices, exposure light is progressively shortened to form a fine pattern. Accordingly, in recent years, an argon fluoride (ArF) excimer laser beam (center wavelength 193 nanometers) has come to be used. A liquid immersion exposure technique has been developed as an exposure technique using the ArF excimer laser beam. According to this liquid immersion exposure technique, a numerical aperture of a projection lens can be set equal to or more than one. Therefore, when an exposure device having the ArF excimer laser beam as exposure light is used, a cycle pattern having a half pitch equal to or smaller than 50 nanometers can be formed (for example, see JP-A H10-303114 (KOKAI)).

A photomask substrate used for exposure using the ArF excimer laser is formed by transparent fused silica. However, this photomask substrate has a slight variation in transmittance. When a fine pattern of which high-precision pattern dimension required in recent years is not required in the past, a slight variation in the transmittance of the photomask substrate is not a problem. However, in the manufacture of a semiconductor device of which fine pattern is progressed in recent years, the slight variation in the transmittance of the photomask becomes an unignorable cause of a variation of exposure. As a result, this variation induces a variation of a size of a pattern formed on the semiconductor substrate (for example, see JP-A 2006-99041 (KOKAI)). Therefore, along with the downscaling of the patterns, a required precision level of exposure and a size of resist on the semiconductor substrate have increased. Further, in the photomask to manufacture a semiconductor memory device in which there is a clear distinction between a region in which high-level size precision is necessary as required by memory cells and a region in which high-level size precision required by the memory cells is not necessary like peripheral circuits, it is necessary to specify a size of transmittance and a variation of the transmittance permissible in each region on the photomask. However, conventionally, specification of transmittance and of a variation of the transmittance of the photomask in each region has not been known.

Further, the above problems are similarly found in the exposure of resist on the semiconductor substrate using light transmitted through the photomask and in the exposure of resist on the semiconductor substrate using light reflected from the photomask.

### BRIEF SUMMARY OF THE INVENTION

A method of obtaining exposure correction information according to an embodiment of the present invention comprises adjusting intensity of light incident on a photomask so that intensity of light output from the photomask has a desired distribution, based on an output-light ratio as a ratio of the intensity of output light that passes through or is reflected by the photomask to the intensity of the incident light, at each position in a plane of the photomask; and obtaining the exposure correction information as a distribution of the adjusted intensity of light incident on the photomask.

A device that obtains exposure correction information according to an embodiment of the present invention comprise an adjusting unit for adjusting intensity of light incident on a photomask so that intensity of light output from the photomask has a desired distribution, based on an output-light ratio as a ratio of the intensity of output light that passes through or is reflected by the photomask to the intensity of the incident light from the light source, at each position in a plane of the photomask; and an obtaining unit for obtaining the exposure correction information as a distribution of the adjusted intensity of light incident on the photomask.

A method of manufacturing a semiconductor device according to an embodiment of the present invention comprises adjusting intensity of light output from a photomask, based on an output-light ratio as a ratio of the intensity of output light that passes through or is reflected by the photomask to the intensity of incident light, at each position in a plane of the photomask; and exposing a semiconductor substrate through the adjusted intensity of light.

### BRIEF DESCRIPTION OF THE DRAWINGS

FIG. 1 is a schematic configuration diagram of an exposure device used in a semiconductor device manufacturing method according to a first embodiment of the present invention;

FIG. 2 is a flowchart of one example of a calculation process of substrate-transmittance distribution information;

FIG. 3A to FIG. 3D are cross-sectional views schematically depicting one example of a procedure of a photomask manufacturing method;

FIG. 4A and FIG. 4B are schematic diagrams for explaining an outline of an exposure correction process of a mask substrate;

FIG. 5A and FIG. 5B depict one example of a schematic configuration of a shape variable slit;

FIG. 6 schematically depicts one example of a pattern formed on a photomask;

FIG. 7 is one example of a relationship between a size of transmittance and a shape variation amount of a photoresist film calculated by an optical simulation;

FIG. 8 is a flowchart of one example of a process procedure of a photomask manufacturing method;

FIG. 9 is a flowchart of one example of another process procedure of the photomask manufacturing method;

FIG. 10A to FIG. 10D schematically depict a state having a mask substrate and a mask pattern relatively rotated and superimposed;

FIG. 11 is a flowchart of one example of a photomask manufacturing method according to a fourth embodiment of the present invention;

FIG. 12 depicts a schematic configuration of an EUV exposure device; and

FIG. 13 schematically depicts one example of a cross-sectional configuration of a reflection photomask.

### DETAILED DESCRIPTION OF THE INVENTION

Exemplary embodiments of a device and a method for obtaining exposure correction information, and manufacturing method of semiconductor device according to the present invention will be explained below in detail with reference to the accompanying drawings. The present invention is not limited thereto. Cross-sectional views of photomasks referred to in the following embodiments are schematic, and therefore, a relationship between a thickness and a width of a layer and a ratio of thicknesses of layers are different from relationships and ratios of actual products.

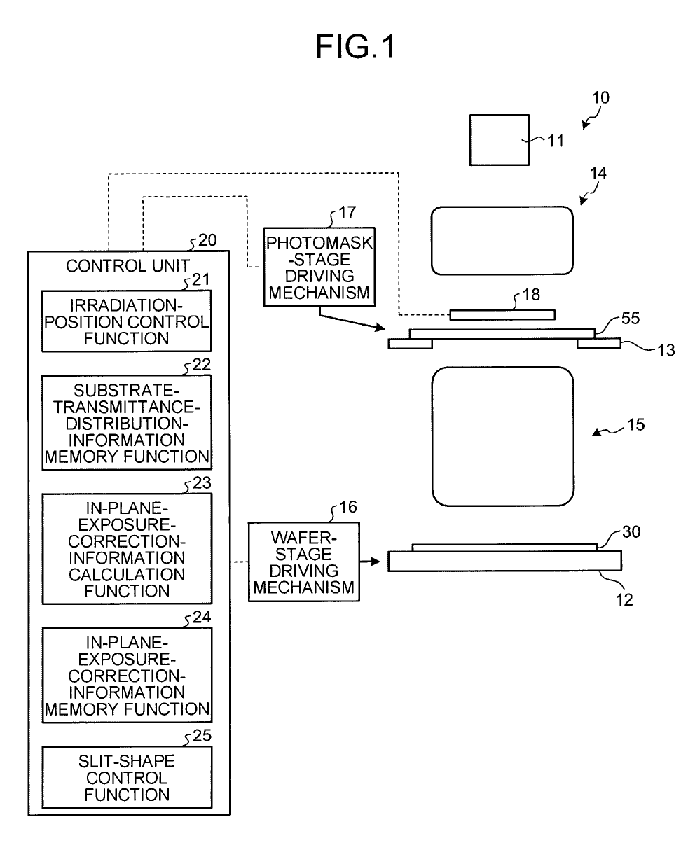

FIG. 1 is a schematic configuration diagram of an exposure device used in a semiconductor device manufacturing method according to a first embodiment of the present invention. This exposure device 10 includes: a light source 11 including a laser beam source that outputs ArF excimer laser beam, for example; a wafer stage 12 to mount thereon a semiconductor substrate (wafer) 30 to be processed; a photomask stage 13 provided between the light source 11 and the wafer stage 12 and to mount thereon a photomask 55; an illumination optical system 14 that irradiates light from the light source 11 to the photomask 55; a projection optical system 15 that projects light transmitted through the photomask 55, onto the semiconductor substrate 30; a wafer-stage driving mechanism 16 that drives the wafer stage 12 to a predetermined direction; a photomask-stage driving mechanism 17 that drives the photomask stage 13 to a predetermined direction; a shape variable slit 18 provided at a side of the light source 11 of the photomask stage 13 to control amount of light (exposure) transmitted through the photomask 55; the wafer-stage driving mechanism 16; and a control unit 20 that controls the wafer-stage driving mechanism 16, the photomask-stage driving mechanism 17, and the shape variable slit 18.

The control unit 20 includes: an irradiation-position control function 21; a substrate-transmittance-distribution-information memory function 22; an in-plane-exposure-correction-information calculation function 23; an in-plane-exposure-correction-information memory function 24; and a slit-shape control function 25.

The irradiation-position control function 21 controls the wafer-stage driving mechanism 16 and the photomask-stage driving mechanism 17 to synchronously move the wafer stage 12 and the photomask stage 13 to expose a predetermined pattern onto a predetermined region on the semiconductor substrate 30.

The substrate-transmittance-distribution-information memory function 22 stores substrate-transmittance distribution information indicating an in-plane transmittance distribution at each position in the in-plane of the photomask 55.

The in-plane-exposure-correction-information calculation function 23 calculates exposure irradiated to each position of the photomask 55 so that an in-plane exposure distribution in a region exposed on the semiconductor substrate 30 through the photomask 55 at an exposure processing time becomes uniform, based on substrate-transmittance distribution information stored in the substrate-transmittance-distribution-information memory function 22. The exposure at each position on the photomask 55 is called in-plane-exposure correction information, and this information corresponds to exposure correction information in the appended claims. The in-plane-exposure-correction-information memory function 24 stores the in-plane-exposure correction information calculated by the in-plane-exposure-correction-information calculation function 23.

The slit-shape control function 25 controls a shape of the shape variable slit 18, based on the in-plane-exposure correction information stored in the in-plane-exposure-correction-information memory function 24. How to change the shape of the shape variable slit 18 is described later.

Each configuration processing unit constituting the control unit 20 can be configured by one information processing device, or can be configured by an information processing device prepared for each function. The in-plane-exposure-correction-information calculation function 23 corresponds to a device that obtains exposure correction information in the claims.

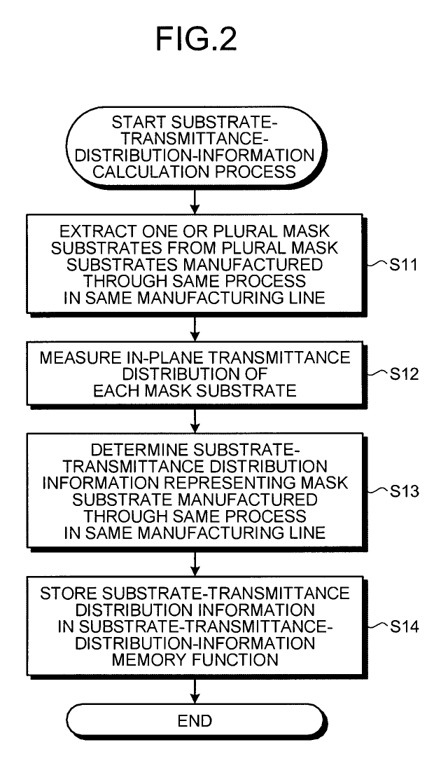

A process of calculating substrate-transmittance distribution information stored in the substrate-transmittance-distribution-information memory function 22 is explained next. FIG. 2 is a flowchart of one example of the calculation process of the substrate-transmittance distribution information. First, one or plural mask substrates are extracted from plural photomask substrates (hereinafter, “mask substrates”) serving as a basis of the photomask 55 manufactured through the same process in the same manufacturing line (Step S11). When the light source 11 is an ArF excimer laser-beam source, a quartz substrate, for example, is used for the mask substrate.

Next, an in-plane transmittance distribution of light having the same wavelength as that of the light source 11 used in the exposure device 10 is measured for each mask substrate extracted (Step S12). The transmittance can be obtained as a ratio of intensity of output light to intensity of input light (corresponding to an output-light ratio in the claims), after measuring intensity (the intensity of input light) on a light input-side surface of the mask substrate and intensity (the intensity of output light) on a light output-side surface of the mask substrate. The in-plane transmittance distribution is obtained by obtaining transmittance at each position within the mask substrate plane.

Thereafter, substrate-transmittance distribution information representing a mask substrate manufactured through the same process in the same manufacturing line is determined using the in-plane transmittance distribution measured for each mask substrate (Step S13). When plural mask substrates are measured, for example, an average value of in-plane transmittance distributions of all measured mask substrates can be obtained as representative substrate-transmittance distribution information. When one mask substrate is measured, the in-plane transmittance distribution of the measured mask substrate is obtained as representative substrate-transmittance distribution information. The determined substrate-transmittance distribution information is stored in the substrate-transmittance-distribution-information memory function 22 (Step S14), and the calculation process of the substrate-transmittance distribution information is finished. Thereafter, the photomask 55 is manufactured from the mask substrate manufactured through the same process in the same manufacturing line corresponding to the calculated substrate-transmittance distribution information.

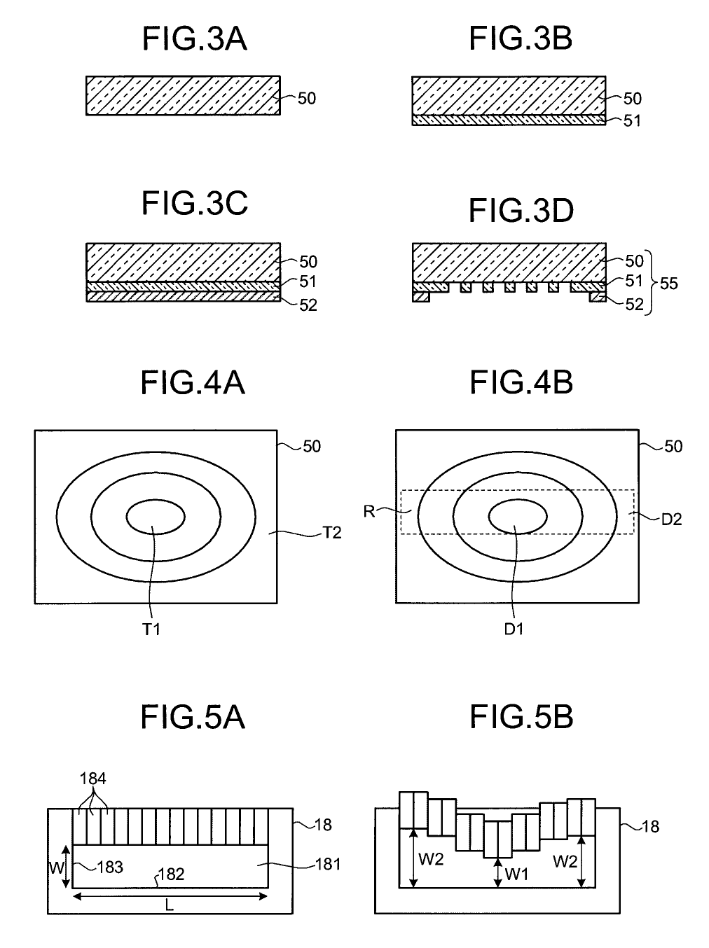

FIG. 3A to FIG. 3D are cross-sectional views schematically depicting one example of a procedure of the photomask manufacturing method. First, a translucent film 51 made of MoSi or the like is formed as shown in FIG. 3B, on the entire surface of one main surface of a mask substrate 50 (a quartz substrate, for example) shown in FIG. 3A. Next, as shown in FIG. 3C, a light shielding film 52 including Cr or the like is formed on the entire surface of the translucent film 51. This light shielding film 52 includes a half tone film. Thereafter, resist is coated on the light shielding film 52, a pattern is drawn by a method such as electronic light exposure, and a result is developed, thereby forming a resist pattern. As shown in FIG. 3D, the light shielding film 52 and the translucent film 51 are etched using the resist pattern as a mask. Further, the light shielding film 52 in a region used for the exposure is removed, thereby manufacturing the photomask 55.

In the above explanations of the first embodiment with reference to FIG. 2, FIG. 3A to FIG. 3D, the calculation is performed using the in-plane transmittance distribution of the mask substrate 50, on which nothing is formed, manufactured through the same process in the same manufacturing line, as the substrate-transmittance distribution information. However, the information used is not limited thereto. For example, when any mask substrate 50 can be formed to have the same film thickness of the translucent film 51 at each position on the mask substrate 50 and have the same shape and size at each position of a pattern, substrate-transmittance distribution information after forming the translucent film 51 shown in FIG. 3B can be used, or substrate-transmittance distribution information after forming the pattern shown in FIG. 3D can be used. When substrate-transmittance distribution information is obtained as shown in FIG. 3D, the substrate-transmittance distribution information includes influence of diffraction due to a pattern shape of the translucent film 51 in addition to the transmittance due to materials of the mask substrate 50 and the translucent film 51. Therefore, this substrate-transmittance distribution information can be used only for the photomask 55 having exactly the same pattern.

Subsequently, correction process of in-plane exposure in the exposure process using the substrate-transmittance distribution information is explained. An outline of the exposure process performed by the exposure device 10 is explained first. In the exposure process, exposure is performed by scanning, in a width direction of one rectangular shot region on the semiconductor substrate 30, a rectangular exposure region having the same length as that of the rectangular shot region on the semiconductor substrate 30 and having a smaller width than that of this rectangular shot region. That is, exposure light from the light source 11 is usually formed in a slit shape, and is irradiated onto the semiconductor substrate 30 through the photomask 55, thereby forming a slit exposure region on the semiconductor substrate 30. The photomask-stage driving mechanism 17 and the wafer-stage driving mechanism 16 relatively scan the photomask stage 13 and the wafer stage 12 in a width direction of the slit (the exposure region), thereby transferring the pattern of the photomask 55 to the rectangular shot region set on the semiconductor substrate 30.

However, as described above, because the photomask 55 has a transmittance distribution of exposure light in the plane, a straight exposure generates a distribution corresponding to the in-plane transmittance distribution of the photomask 55 (the mask substrate 50), in the exposure on the semiconductor substrate 30. Therefore, in the first embodiment, exposure is performed using the shape variable slit 18 capable of changing the width of the slit corresponding to the transmittance distribution of the photomask 55 irradiated.

A method of calculating the in-plane-exposure correction information serving as a basis of changing a slit width of the shape variable slit 18 is explained next. The in-plane-exposure-correction-information calculation function 23 of the control unit 20 calculates this in-plane-exposure correction information.

FIG. 4A and FIG. 4B are schematic diagrams for explaining an outline of the exposure correction process of the mask substrate. FIG. 4A is one example of a transmittance distribution of the mask substrate, and FIG. 4B is one example of a transmittance distribution to make uniform the exposure within the mask substrate. As shown in FIG. 4A, it is assumed that transmittance of the mask substrate 50 is high in the center, and decreases concentrically from the center of the mask substrate 50. As shown in FIG. 4B, to make uniform in the plane the amount of light transmitted through the mask substrate 50, the amount of light (exposure) input to each position is set inversely proportional to the transmittance at this position. For example, when the transmittance at the center of the mask substrate 50 is T1 and when the transmittance at the periphery of the mask substrate 50 is T2 (<T1) in FIG. 4A, the exposures D1 and D2 at these positions (see FIG. 4B) satisfy the following equation (1):

D1:D2=1/T1:1/T2 (1)

As explained above, by irradiating light to each in-plane position of the photomask 55 by an irradiation amount inversely proportional to the in-plane transmittance distribution of the mask substrate 50, intensity of the light transmitted through the photomask 55 becomes the same at each in-plane position after passing the photomask 55. The in-plane exposure distribution obtained in this way is stored in the in-plane-exposure-correction-information memory function 24 as the in-plane-exposure correction information.

The in-plane-exposure correction information does not need to be the in-plane exposure distribution. For example, a deviation of exposure from the exposure serving as a basis can be obtained from the in-plane exposure distribution obtained in the manner as described above, and then a distribution of a deviation of the in-plane exposure can be obtained. The last distribution obtained can be the in-plane-exposure correction information.

A semiconductor device manufacturing method using the exposure device 10 shown in FIG. 1 is explained next. First, the photomask 55 formed with a pattern to be transferred to a film to be processed is mounted on the photomask stage 13 of the exposure device 10, using the mask substrate 50 manufactured in the same manufacturing line and the same process as those used to calculate substrate-transmittance distribution information. The semiconductor substrate 30 sequentially formed with the film to be processed and the resist is mounted on the wafer stage 12.

Next, the irradiation-position control function 21 of the control unit 20 outputs signals to the photomask-stage driving mechanism 17 and the wafer-stage driving mechanism 16, matches positions between the photomask 55 and the semiconductor substrate 30, and exposes light from the light source 11 to the semiconductor substrate 30 through the photomask 55. The irradiation-position control function 21 outputs signals to the photomask-stage driving mechanism 17 and the wafer-stage driving mechanism 16, and scans the photomask stage 13 and the wafer stage 12. In this case, the slit-shape control function 25 of the control unit 20 changes the shape of the shape variable slit 18, based on the in-plane-exposure correction information stored in the in-plane-exposure-correction-information memory function 24 corresponding to the exposure position to the wafer stage 12.

In irradiating a region R in the photomask (the mask substrate 50) shown in FIG. 4B, for example, the irradiation is performed to have an in-plane exposure distribution shown in the region R. That is, because the exposure gradually becomes large from exposure D1 at the center toward exposure D2 at the periphery, a shape of the shape variable slit 18 is changed to have this change of exposure.

FIG. 5A and FIG. 5B depict one example of a schematic configuration of a shape variable slit. As shown in FIG. 5A, this shape variable slit 18 basically has a substantially rectangular shape of a region (a light pass region) 181 through which light passes. A length L of the light pass region 181 is equal to a length of a shot region on the semiconductor substrate 30, and a width W of the light pass region 181 is smaller than the length of the shot region. A side in a direction equal to the length of the shot region is called a long side 182, and a side in the other direction is called a short side 183.

The long side 182 of the light pass region 181 includes plural strip side-configuration members 184 movable in an extension direction of the short side 183. In irradiating light to the region R shown in FIG. 4B, positions of the side configuration members 184 in a direction of the short side 183 are controlled so that a width W1 near the center of the long side 182 of the shape variable slit 18 becomes small and a width W2 near the periphery of the long side 182 becomes large as shown in FIG. 5B. In this case, the width W1 near the center of the long side 182 and the width W2 at the periphery of the long side 182 are proportional to the exposures D1 and D2, respectively.

As explained above, the slit-shape control function 25 can make uniform the irradiation amount of light at each position of the semiconductor substrate 30, by changing a width at each position of the long side 182 of the shape variable slit 18, based on the in-plane correction information at the position of the photomask 55 to be irradiated.

The distribution of exposure within the exposure region is influenced by a variation of luminance of the light source 11 and a variation of resist coated on the semiconductor substrate 30 as well as by the substrate-transmittance distribution. Therefore, exposure distributions due to these factors can be also corrected. In this case, a total correction amount is calculated by combining a correction amount of the substrate transmittance distribution described above and a correction amount of exposure due to other factors, and the exposure distribution can be controlled based on a result of the calculation.

In the general exposure process, illumination light incident to the photomask 55 at an angle within a range of 0 to about 20 degrees relative to a normal line of a pattern formation plane of the photomask 55 is used. Therefore, in measuring the in-plane transmittance distribution, it is preferable to use light having an incident angle of the range from 0 to about 20 degrees. For example, the in-plane transmittance distribution is measured using light having an incident angle of the range from 0 to about 20 degrees, and an averaged in-plane transmittance distribution can be stored in a substrate-transmittance-distribution-information memory unit.

Further, while the intensity of light output from the photomask 55 is made uniform in the above explanations, an incident-light intensity distribution of light input to the photomask 55 can be also adjusted so that the intensity of light output from the photomask 55 becomes a desired intensity distribution.

According to the first embodiment, the in-plane transmittance distribution of light having a wavelength used in the exposure device 10 of the photomask 55 is measured, and the irradiation amount of light to each position of the photomask 55 is changed corresponding to the in-plane transmittance distribution. Therefore, the exposure of light reaching the semiconductor substrate 30 through the photomask 55 at each position on the semiconductor substrate 30 becomes uniform. As a result, resist size precision on the semiconductor substrate 30 can be increased. Further, exposure correction information to be used to correct the exposure can be obtained against a slight variation of transmittance of light through the photomask.

A semiconductor device according to a second embodiment of the present invention uses a photomask that obtains a variation of in-plane transmittance of a mask substrate, has a layout of a pattern requiring a high-level size control for a resist pattern transferred to a semiconductor substrate, in a region having a transmittance variation smaller than a predetermined value, and has a layout of a pattern not requiring high-level size precision, in a region of poor transmittance or in a region having a larger transmittance variation than a predetermined value. The manufacturing of the semiconductor device according to the second embodiment is explained below.

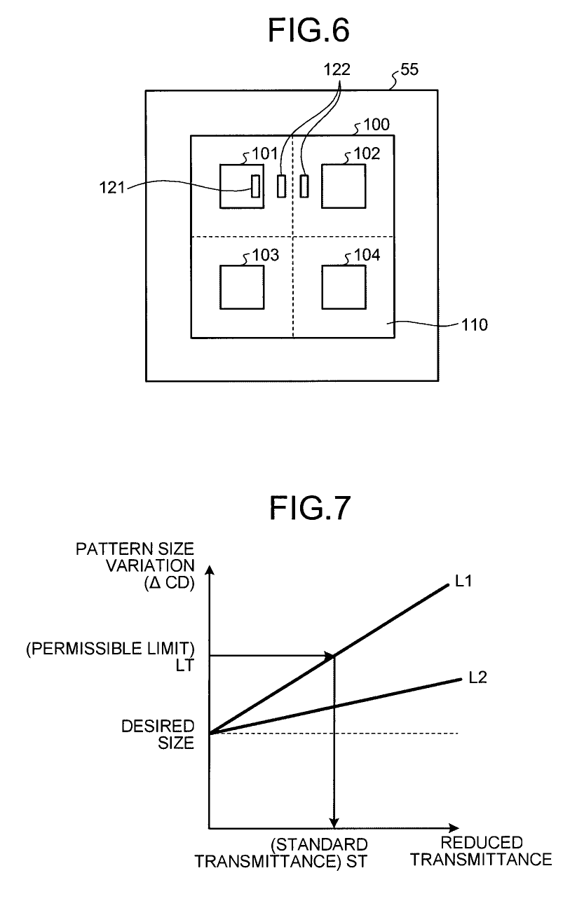

FIG. 6 schematically depicts one example of a pattern formed on a photomask. A mask pattern region 100 in which a mask pattern of the photomask 55 is formed is divided into high-precision management regions 101 to 104 in which a pattern requiring fine and high-precision size management is present, and a low-precision management region 110 in which a pattern not requiring fine and high-precision size management as required by the high-precision management regions 101 to 104 is present.

As a method of setting the high-precision management regions 101 to 104, for example, the high-precision management regions 101 to 104 can be chip regions including mutually adjacent plural wiring groups and including a wiring pattern of which half pitch is equal to or smaller than one third of a wavelength of illumination light of an exposure device. For instance, when an exposure device having ArF excimer laser beam (center wavelength 193 nanometers) as an exposure light source is used for a photolithography process, chip regions including line-and-space wiring groups having 65 nanometers as a half pitch are set as the high-precision management regions 101 to 104.

To form the high-precision management regions 101 to 104, a standard value is provided in the regions corresponding to the high-precision management regions 101 to 104 of the mask substrate. That is, for the in-plane transmittance in the corresponding regions on the mask substrate on which the high-precision management regions 101 to 104 are formed, the standard value is set so that a variation of a size of a pattern formed on the resist on the semiconductor substrate becomes equal to or smaller than a predetermined value. The standard value is set so that the in-plane transmittance of the mask substrate becomes equal to or larger than a predetermined value or a variation of the substrate transmittance becomes equal to or smaller than a predetermined value.

In the example shown in FIG. 6, the standard value is not set to the low-precision management region 110, and standard values are set to the high-precision management regions 101 to 104. The standard values set in the high-precision management regions 101 to 104 are assumed to be the same. Therefore, a pattern 121 included in the high-precision management regions 101 to 104 shown in FIG. 6 requires a high-precision size management. Patterns 122 included in the low-precision management region 110, and arranged between the high-precision management region 101 and the high-precision management region 102, for example, are larger than the pattern 121, and do not require a high-precision size management. For example, the pattern 121 is a part of a wiring group having a smaller wiring width and a smaller wiring pitch than those of the wiring groups in which the patterns 122 are included.

A method of setting the standard value is explained. First an optical simulation is performed to obtain a relationship between transmittance of the mask substrate 50 or a size of a variation of the transmittance of the mask substrate 50 and a size of a shape variation (hereinafter, “shape variation”) of a width of a pattern formed on a photoresist film on the semiconductor substrate 30 by having the pattern on the photomask 55 manufactured from the mask substrate 50 transferred to the semiconductor substrate 3. The “optical simulation” means performing calculation of an estimate light-intensity distribution that will be formed on the surface of the semiconductor substrate 30 when illumination light transmitted through the photomask 55 reaches the semiconductor substrate 30, and performing virtual calculation of a shape variation amount of a photoresist film that will be formed on the semiconductor substrate 30 due to a shape of a pattern on the photomask 55, an exposure error, and a focus error of the semiconductor substrate 30, based on the calculated light intensity distribution.

FIG. 7 is one example of a relationship between a size of transmittance and a shape variation amount of the photoresist film calculated by the optical simulation. A straight line L1 shown in FIG. 7 expresses a permissible shape-variation amount ΔCD of a pattern of the photoresist film to form the pattern 121 in the high-precision management region 101 shown in FIG. 6 onto the semiconductor substrate. That is, the straight line L1 expresses a size of an influence that the pattern 121 in the high-precision management regions 101 to 104 receives from the transmittance. On the other hand, a straight line L2 expresses a permissible shape-variation amount ΔCD of a resist film to form the pattern 122 in the low-precision management region 110 onto the semiconductor substrate. As shown in FIG. 7, the influence of the size of the substrate transmittance to the shape variation amount ΔCD of the pattern 122 within the low-precision management region 110 is smaller than the influence given to the pattern 121 within the high-precision management regions 101 to 104. In FIG. 7, while the size of transmittance is represented in the lateral axis, the variation of transmittance can be represented in the lateral axis.

The standard value is set within the mask substrate 50, using a result of the optical simulation. For example, using a graph shown in FIG. 7, the standard value ST of transmittance of the mask substrate 50 on which the high-precision management regions 101 to 104 are formed is set, based on a permissible limit LT of the shape variation amount ΔCD of the photoresist film to form the pattern 121.

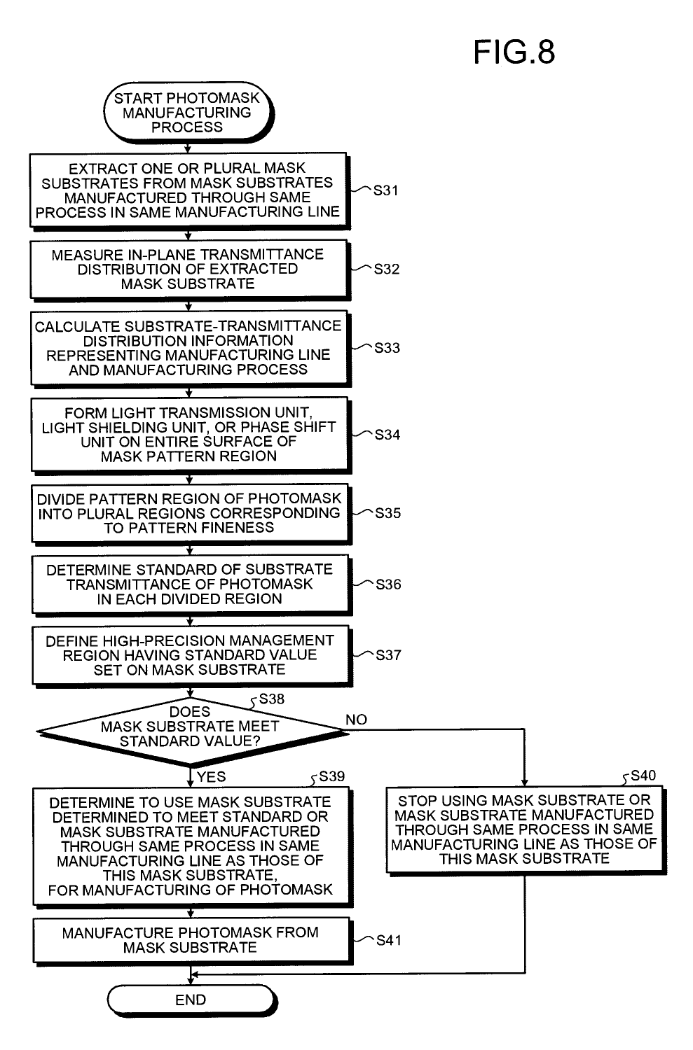

A method of manufacturing the photomask 55 is explained next. FIG. 8 is a flowchart of one example of a process procedure of the photomask manufacturing method. First, one or plural mask substrates 50 are extracted (sampled) among the mask substrate 50 manufactured through the same process in the same manufacturing line (Step S31), and an in-plane transmittance distribution of each mask substrate 50 is measured, as explained in the first embodiment (Step S32). Substrate-transmittance distribution information representing the mask substrate 50 manufactured through the same process in the same manufacturing line is calculated (Step S33). As explained in the first embodiment, when plural samples are present, for example, an average value of in-plane transmittance distributions of all measured mask substrates 50 is obtained as substrate-transmittance distribution information representing the manufacturing line and the manufacturing process. When one sample is present, a measured value of this sample is set as substrate-transmittance distribution information representing the manufacturing line and the manufacturing process. In the actual exposure process, the exposure is performed using light having an incident angle of a range from 0 to about 20 degrees relative to a normal line of a pattern formation plane of the photomask 55. Therefore, it is preferable to calculate an average of in-plane transmittance distributions of light having an incident angle of the range from 0 to about 20 degrees.

Subsequently, a light transmission unit, a light shielding unit, or a phase shift unit is formed on the entire surface on the mask pattern region 100 including the high-precision management regions 101 to 104 (Step S34). Thereafter, a pattern formed on the mask substrate 50 is divided into plural regions corresponding to pattern fineness (Step S35). For example, the pattern is divided into the high-precision management regions 101 to 104 in which the pattern 121 requiring fine and high-precision size management is present, and the low-precision management region 110 in which the pattern 122 not requiring fine and high-precision size management as required by the high-precision management regions 101 to 104 is present. Particularly, a region in which a pattern that generates a size change due to a change of the transmittance of the mask substrate 50 is specified.

A standard value of transmittance (or a size of a transmittance distribution) of the mask substrate 50 required in the high-precision management regions 101 to 104 is determined next (Step S36). Specifically, a relationship between a size of substrate transmittance (or a size of a transmittance distribution) and a size variation of a resist pattern transferred onto the semiconductor substrate is obtained by optical simulation considering a mask pattern to be formed and an illumination condition of an exposure device as explained with reference to FIG. 7. A lower limit size of substrate transmittance (or an upper limit size of a transmittance distribution) is obtained from size precision required for the resist pattern, and the obtained value is used as a standard value required for the high-precision management regions 101 to 104.

For example, the standard value of each region (the high-precision management regions 101 to 104) of a part or the whole of the mask substrate 50 is determined using a result of the optical simulation shown in FIG. 7. More specifically, the standard value ST of a corresponding region on the mask substrate 50 on which the high-precision management regions 101 to 104 are formed is set, based on the permissible limit LT of the shape variation amount ΔCD of the photoresist film to form the pattern 121 shown in FIG. 6.

Next, the high-precision management regions 101 to 104 having the standard value set on the mask substrate 50 are defined (Step S37), and it is determined whether the mask substrate 50 to be used meets the determined standard value (Step S38). In this case, positions of testing substrate transmittance within the region defined as the high-precision management regions 101 to 104 can be increased (test density can be set high), and positions of testing substrate transmittance within the low-precision management region 110 can be reduced (test density can be set low) as compared with the test density of the region defined as the high-precision management regions 101 to 104, or this region can be arranged to have no test. With this arrangement, the testing time of the mask substrate 50 can be shortened.

When the in-plane transmittance distribution of the mask substrate 50 meets the determined standard value (YES at Step S38), for example, when degradation of the substrate transmittance within the region on the mask substrate 50 corresponding to the high-precision management regions 101 to 104 is small (or when a variation of transmittance is small), it is determined that this mask substrate 50 or the mask substrate 50 manufactured through the same process in the same manufacturing line as those of this mask substrate 50 is used to manufacture the photomask 55 (Step S39).

On the other hand, when the in-plane transmittance distribution of the mask substrate 50 does not meet the determined standard value (NO at Step S38), for example, when substrate transmittance within the high-precision management regions 101 to 104 is degraded more than a permissible range (or when a variation of transmittance exceeding the permissible range occurs), the use of this mask substrate 50 is stopped (Step S40). That is, the manufacturing process of the photomask 55 of this mask substrate 50 or the mask substrate 50 manufactured through the same process in the same manufacturing line as those of this mask substrate 50 is finished, and the mask substrate 50 having a different transmittance distribution characteristic is prepared, and the above process is repeatedly performed again from Step S31.

After Step S39, patterning is performed in the light transmission unit, the light shielding unit, or the phase shift unit of the mask substrate 50 that meets the standard value of the transmittance, thereby manufacturing the photomask 55 (Step S41). This mask substrate 50 means the mask substrate 50 of which substrate-in-plane transmittance distribution is measured, or the mask substrate 50 manufactured through the same process in the same manufacturing line as those of this mask substrate 50. The manufacturing process of the photomask 55 is finished with the above process.

When polarized illumination is used as an illumination condition of the exposure device at Step S32, substrate transmittance of polarization light needs to be measured. Particularly, for a mask substrate to be exposed using “s-polarization” of which electric vector oscillation component is perpendicular to a light incident surface, it is preferable to manage substrate transmittance of the s-polarization by measuring this transmittance.

Further, in the exposure process at the time of manufacturing a semiconductor device using the photomask 55 manufactured from the mask substrate 50 having the standard value mentioned above, this exposure process is performed by changing a shape of the shape variable slit 18 so that intensity of light passing through the photomask 55 has a desired distribution such as a uniform distribution, based on the in-plane transmittance distribution of the photomask 55 (the mask substrate 50 serving as a basis of the photomask 55), in a similar manner to that of the first embodiment.

According to the second embodiment, in the high-precision management regions 101 to 104 which are required to have high size precision, light is exposed to the photoresist on the semiconductor substrate, using the photomask 55 manufactured using the mask substrate 50 in which substrate transmittance becomes equal to or larger than a predetermined value or a variation of the substrate transmittance becomes equal to or smaller than a predetermined value. Therefore, size precision of a pattern shape formed on the high-precision management regions 101 to 104 can be increased. Further, for the photomask used to manufacture a semiconductor device, transmittance of the photomask or a variation of transmittance can be managed in each region.

According to the second embodiment, at Steps S37 to S38 in the flowchart shown in FIG. 8, high-precision management regions of the mask pattern regions are defined on the mask substrate, and it is determined whether the transmittance distribution of the mask substrate meets the standard value within these regions. Because the mask substrate is usually square and the mask pattern is rectangular, the mask pattern is arranged so that both sides become parallel. Therefore, there can be a condition that meets the defined standard value of the high-precision management regions, by relatively rotating the mask pattern and the mask substrate. In a third embodiment of the present invention, the mask substrate and the mask pattern are relatively rotated to determine whether there is a state that the substrate transmittance meets the standard value. Finally, it is determined whether this mask substrate is to be used.

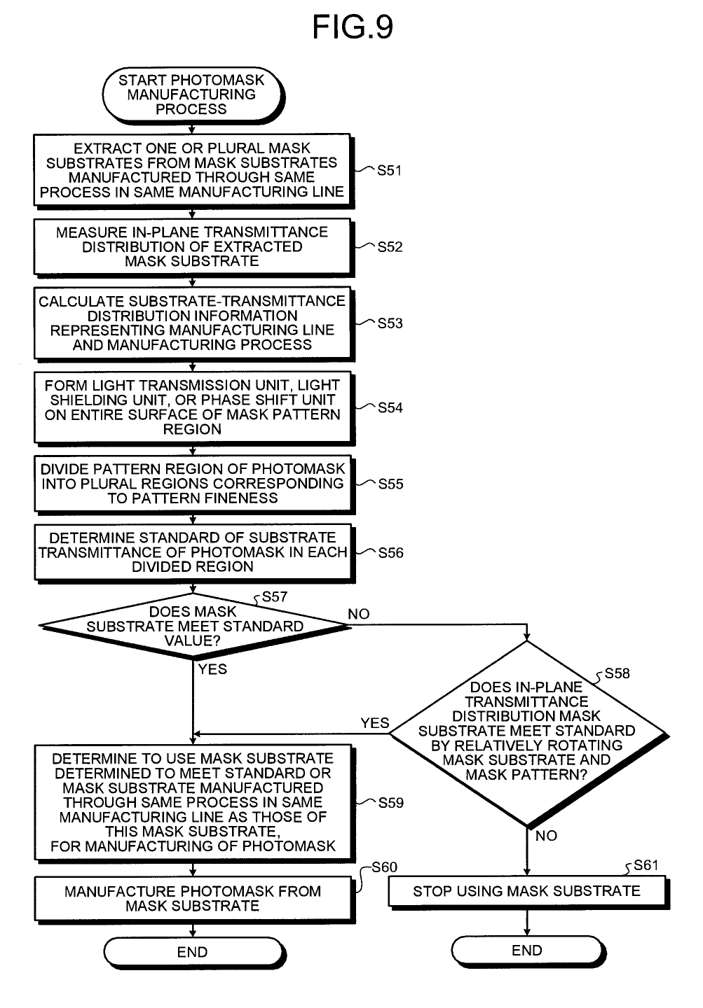

FIG. 9 is a flowchart of one example of a process procedure of a photomask manufacturing method. The mask substrates 50 are manufactured through the same process in the same manufacturing line as those up to Steps S31 to S36 in FIG. 8 in the second embodiment. One or plural mask substrates 50 are extracted from these mask substrates 50, and the in-plane transmittance distributions of the mask substrates 50 are measured, thereby calculating representative substrate-transmittance distribution information. The light transmission unit, the light shielding unit, or the phase shift unit is formed on the mask substrate 50. Thereafter, a mask pattern region is divided into plural regions corresponding to pattern fineness, and a standard value of transmittance is determined in each region (Steps S51 to S56).

The in-plane transmittance distribution of the mask substrate 50 is compared with the standard value regarding the transmittance of the high-precision management regions 101 to 104 within the mask pattern determined at Step S56. Whether the mask substrate 50 meets the determined standard value is determined (Step S57).

When the in-plane transmittance distribution of the mask substrate 50 meets the determined standard value (YES at Step S57), for example, when degradation of the substrate transmittance within the region on the mask substrate 50 corresponding to the high-precision management regions 101 to 104 is small (or when a variation of transmittance is small), it is determined that this mask substrate 50 or the mask substrate 50 manufactured through the same process in the same manufacturing line as those of this mask substrate 50 is used to manufacture the photomask 55 (Step S59).

On the other hand, when the in-plane transmittance distribution of the mask substrate 50 does not meet the determined standard value (NO at Step S57), for example, when substrate transmittance within the high-precision management regions 101 to 104 is degraded more than a permissible range (or when a variation of transmittance exceeding the permissible range occurs), it is determined whether the in-plane transmittance distribution of the mask substrate 50 meets the standard value regarding the transmittance of the high-precision management regions 101 to 104, by relatively rotating the mask pattern and the mask substrate 50 within the pattern formation plane (Step S58).

As described above, because generally the mask substrate 50 is square and the mask pattern region is rectangular, the mask pattern is arranged so that both sides become parallel. Therefore, even when the mask pattern is rotated by 90 degrees, 180 degrees, or 270 degrees relative to the mask substrate from an initial layout state, the photomask 55 can be manufactured by forming a pattern on the mask substrate 50. Therefore, a defective region on the mask substrate 50 in which the substrate transmittance does not meet the standard value can be excluded from the high-precision management regions 101 to 104, in any one of the states that the mask substrate 50 and the mask pattern are relatively rotated by 90 degrees, 180 degrees, and 270 degrees. When a size of substrate transmittance in the corresponding region on the mask substrate 50 where the high-precision management regions 101 to 104 are formed meets the standard value, the photomask 55 can be manufactured by forming a pattern on the mask substrate 50 in the state having the mask pattern rotated.

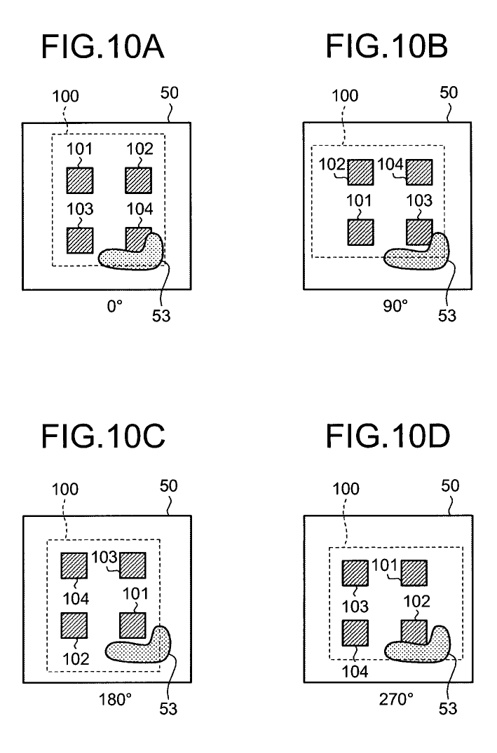

FIG. 10A to FIG. 10D schematically depict a state having a mask substrate and a mask pattern relatively rotated and superimposed. The mask pattern as the mask pattern region 100 where the high-precision management regions 101 to 104 are arranged, and the mask substrate 50 has a defective region 53 where a size of the substrate transmittance does not meet the standard value.

FIG. 10A depicts a relationship between the mask substrate 50 and the mask pattern in a state determined at Step S57. FIG. 10B, FIG. 10C, FIG. 10D show states of the mask substrate 50 and the mask pattern region 100 after rotating the mask pattern region 100 by 90 degrees, 180 degrees, 270 degrees, respectively in a counterclockwise direction from the state shown in FIG. 10A.

In FIG. 10A, FIG. 10B, FIG. 10D, high-precision management regions 104, 103, and 102 are superimposed with the defective region 53, respectively. Therefore, in a layout relationship between the mask substrate 50 and the mask pattern region 100, the mask substrate 50 does not meet the standard value. However, as shown in FIG. 10C, in a state that the mask pattern region 100 is rotated by 180 degrees in a counterclockwise direction from the state shown in FIG. 10A, the defective region 53 of the mask substrate 50 is not superimposed with the high-precision management regions 101 to 104. That is, the photomask 55 can be manufactured by forming a pattern on the mask substrate 50 in the state shown in FIG. 10C.

Referring back to FIG. 9, when the in-plane transmittance distribution of the mask substrate 50 meets the standard by relatively rotating the mask pattern and the mask substrate 50 in the pattern formation plane at Step S58 (YES at Step S58), for example, when the state shown in FIG. 10C is obtained, the process proceeds to Step S59. That is, the mask substrate 50 which is determined to meet this standard or the mask substrate 50 manufactured through the same process in the same manufacturing line as those of this mask substrate 50 is determined to be used to manufacture the photomask 55.

On the other hand, when the in-plane transmittance distribution of the mask substrate 50 does not meet the standard by relatively rotating the mask pattern and the mask substrate 50 in the pattern formation plane at Step S58 (NO at Step S58), there is no condition that meets a required specification of the substrate transmittance of the mask substrate 50 within the high-precision management regions 101 to 104. Therefore, the use of the mask substrate 50 is stopped (Step S61). That is, the manufacturing process of the photomask 55 in this mask substrate 50 or the mask substrate 50 manufactured through the same process in the same manufacturing line as those of this mask substrate 50 is finished. The mask substrate 50 having a different transmittance distribution characteristic is prepared, and the process described above is repeatedly performed again from Step S51.

After Step S59, patterning is performed to the light transmission unit, the light shielding unit, or the phase shift unit of the mask substrate 50 that meets the standard of transmittance, thereby manufacturing the photomask 55 (Step S60). In this case, specification of transmittance is met within the high-precision management regions 101 to 104, considering a direction of a mask rotated at the Step S58. The mask substrate 50 in this case is the mask substrate 50 in which the in-plane transmittance distribution is measured or the mask substrate 50 manufactured through the same process in the same manufacturing line as those of this mask substrate 50. The manufacturing process of the photomask 55 is finished with the above process.

According to the third embodiment, in the manufacturing of the mask substrate 50, at the time of superimposing the mask pattern with the mask substrate 50, when the defective region 53 of the mask substrate 50 is superimposed with the high-precision management regions 101 to 104, the mask substrate 50 and the mask pattern are relatively rotated, thereby searching a condition that the high-precision management regions 101 to 104 of the mask pattern are not superimposed with the defective region 53 of the mask substrate 50. As a result, when a condition that the high-precision management regions 101 to 104 of the mask pattern are not superimposed with the defective region 53 of the mask substrate 50 can be searched by relatively rotating the mask substrate 50 and the mask pattern, probability that the mask substrate 50 is determined as unusable is reduced, and the mask substrate 50 can be effectively used. Consequently, the manufacturing cost of the semiconductor device can be also reduced as compared to conventional manufacturing methods.

In a fourth embodiment of the present invention, a mask substrate manufacturer is different from a photomask manufacturer, and the mask manufacturer selects a mask substrate. An example of a photomask manufacturing method in this case is explained below.

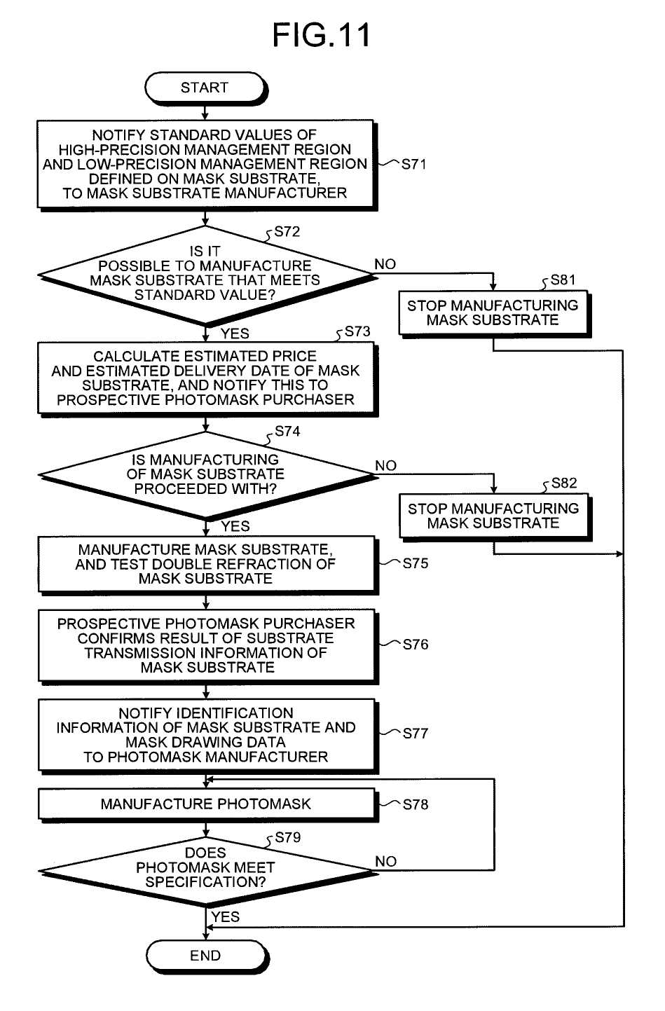

FIG. 11 is a flowchart of one example of a photomask manufacturing method according to the fourth embodiment. First, a prospective photomask purchaser such as a semiconductor device manufacturer defines on the mask substrate a high-precision management region where an element pattern requiring high-precision size management is formed and a low-precision management region where an element pattern not requiring high-precision size management is formed. The prospective photomask purchaser determines a standard value of a size of transmittance or a size of a transmittance variation in each region (Step S71). The mask pattern region 100 shown in FIG. 6 is taken here as an example. The prospective photomask purchaser determines the high-precision management regions 101 to 104 and the low-precision management region 110 within the mask pattern region 100. The prospective photomask purchaser determines standard values in the high-precision management regions 101 to 104 and the low-precision management region 110, respectively, and notifies the substrate manufacturer of the set values. A standard value does not need to be set in the low-precision management region 110.

The mask substrate manufacturer then determines whether it is possible to manufacture the mask substrate 50 that meets the standard values in the high-precision management regions 101 to 104 and the low-precision management region 110 transmitted from the prospective photomask purchaser (Step S72). When the mask substrate 50 that meets the standard value cannot be manufactured (NO at Step S72), the mask substrate manufacturer notifies the prospective photomask purchaser this information, and stops manufacturing the mask substrate (Step S81). The process is finished there. On the other hand, when the mask substrate 50 that meets the standard value can be manufactured (YES at Step S72), the mask substrate manufacturer calculates an estimated price of the mask substrate 50 and an estimated delivery date based on past manufacturing information and price information (Step S73). The calculated estimated price and the estimated delivery date of the mask substrate 50 are notified to the prospective photomask purchaser.

Thereafter, the prospective photomask purchaser determines whether to proceed with the manufacturing of the mask substrate 50 and the photomask based on the notified estimated price and estimated delivery date of the mask substrate 50, and informs the result of the determination to the mask substrate manufacturer (Step S74). On the other hand, when the manufacturing of the mask substrate 50 is not proceeded with, this information is notified to the mask substrate manufacturer, and the manufacturing of the mask substrate 50 is stopped (Step S82). The mask manufacturing process is finished there. When the manufacturing of the mask substrate 50 and the photomask 55 is to be proceeded with, the process proceeds to Step S75.

The mask substrate manufacturer then produces the mask substrate 50 by receiving the determination of manufacturing the mask substrate 50 from a prospective photomask purchaser. The mask substrate manufacturer performs a test on the in-plane transmission distribution of the manufactured mask substrate 50 using the method already explained, and calculates the substrate-transmittance distribution information (Step S75). The result of the test is notified to the prospective photomask purchaser.

Thereafter, the prospective photomask purchaser confirms the test result of the substrate-transmittance distribution information of the mask substrate 50 (Step S76). The prospective photomask purchaser notifies the photomask manufacturer about identification information of the manufactured mask substrate 50 and mask drawing data (Step S77). Upon receiving this information from the prospective photomask purchaser, the photomask manufacturer receives the mask substrate 50 from the mask substrate manufacturer. The photomask manufacturer forms a pattern on the mask substrate 50, using the mask drawing data received from the prospective photomask purchaser, and manufactures the photomask 55 (Step S78).

The photomask manufacturer performs tests on a size and a defect of the manufactured photomask 55, ships the photomask 55 that meets the defined specification of the photomask 55, to the prospective photomask purchaser (Step S79), and finishes the photomask manufacturing process. When the photomask 55 does not meet the defined specification, the process returns to Step S78, and the photomask 55 is manufactured again.

According to the fourth embodiment, even when the mask substrate manufacturer, the photomask manufacturer, and the prospective photomask purchaser are different, a photomask can be manufactured using a mask substrate that meets the standard value of the substrate transmittance or the standard value of a variation of substrate transmittance.

In the first to fourth embodiments, a transmission photomask is used. However, when light of a very short wavelength such as 10 to 14 nanometers is used as used by an extreme ultra violet (EUV) exposure device, light is substantially absorbed, and therefore, the transmission photomask cannot be used in this case. Accordingly, a reflection photomask is used in the EUV exposure device. The first to fourth embodiments can be also applied to this reflection photomask.

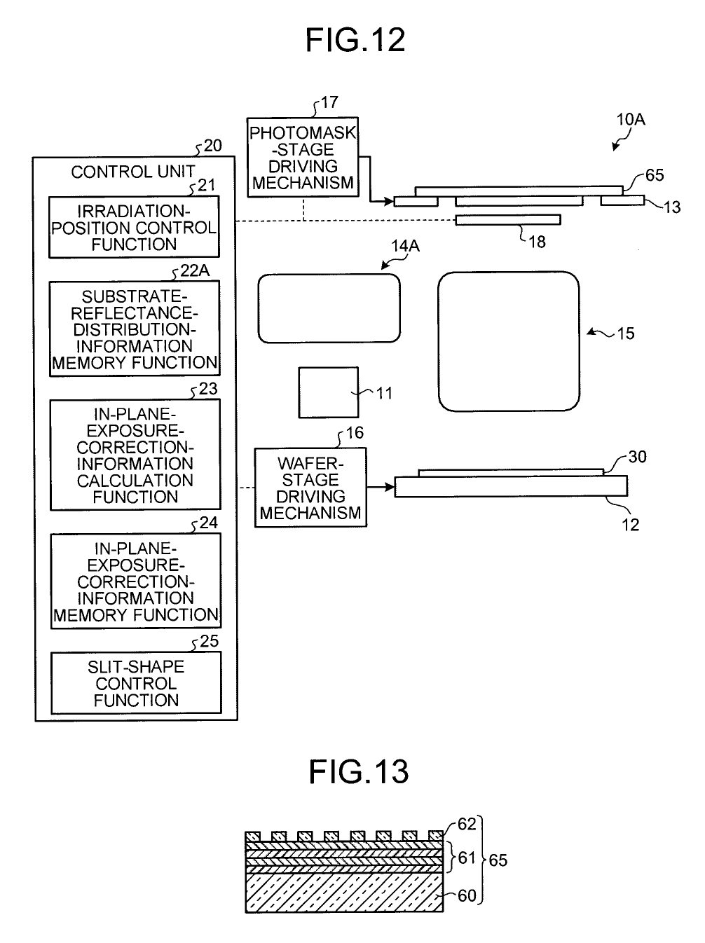

FIG. 12 depicts a schematic configuration of the EUV exposure device. This EUV exposure device 10A includes: the light source 11 that outputs X rays having a short wavelength; the wafer stage 12 on which the semiconductor substrate (the wafer) 30 to be processed is mounted; the photomask stage 13 provided between the light source 11 and the wafer stage 12, and having a reflection photomask 65 mounted thereon; an illumination optical system 14A that illuminates by reflection light from the light source 11 onto the reflection photomask 65; the projection optical system 15 that projects by reflection light transmitted through the reflection photomask 65 onto the semiconductor substrate 30; the wafer-stage driving mechanism 16 that drives the wafer stage 12 to a predetermined direction; the photomask-stage driving mechanism 17 that drives the photomask stage 13 to a predetermined direction; the shape variable slit 18 provided at a side of the light source 11 of the photomask stage 13 to control amount of light (exposure) transmitted through the reflection photomask 65; the wafer-stage driving mechanism 16; and the control unit 20 that controls the wafer-stage driving mechanism 16, the photomask-stage driving mechanism 17, and the shape variable slit 18. The reflection photomask 65 has a configuration to guide by reflection the light from the illumination optical system 14A to the projection optical system 15. The configuration of the control unit 20 is identical to that of the first embodiment except that the substrate-transmittance-distribution-information memory function 22 shown in FIG. 1 in the first embodiment is replaced by a substrate-reflectance-distribution-information memory function 22A, and that the in-plane exposure correction information is calculated using reflectance instead of the transmittance of the mask substrate. Therefore, explanations of the configuration of the control unit 20 will be omitted.

FIG. 13 schematically depicts one example of a cross-sectional configuration of the reflection photomask. The reflection photomask 65 includes: a mask substrate 60 such as silica glass, for example; a reflection layer 61 that includes a multilayer film having different kinds of films such as molybdenum and silicon (Mo/Si) or beryllium and silicon (Be/Si) alternately laminated, on the mask substrate 60; and an absorption pattern 62 that absorbs soft X rays including tantalum nitride (TaN) having a desired pattern formed on the reflection layer 61.

A method of manufacturing the reflection photomask 65 and a method of manufacturing a semiconductor device using the reflection photomask 65 can be applied to the first to fourth embodiments. In the reflection photomask 65, one or plural mask substrates 60 are extracted from the mask substrates 60 manufactured through the same process in the same manufacturing line. An in-plane reflectance distribution as a rate of intensity of reflected light to intensity of light incident to each position in the plane of the mask substrate 60 is measured, in a state having the reflection layer 61 formed on each mask substrate 60. Substrate-reflectance distribution information representing the same process in the same manufacturing line is calculated from this in-plane reflectance distribution. In measuring the in-plane reflectance distribution, an in-plane reflectance distribution of the photomask 65 having the absorption pattern 62 further formed on the mask substrate 60 formed with the reflection layer 61 can be measured, in place of the mask substrate 60 formed with the reflection layer 61. The obtained substrate-transmittance distribution information can be used.

A semiconductor substrate manufacturing method using this reflectance photomask 65 is identical to that of the first embodiment except that instead of using the substrate-transmittance distribution information, the substrate-reflectance distribution information is used, in the semiconductor device manufacturing method explained in the first embodiment. Therefore, explanations of the method of manufacturing the semiconductor substrate using the reflectance photomask 65 will be omitted.

According to a fifth embodiment of the present invention, an in-plane reflectance distribution of light having a wavelength used in the exposure device of the reflection photomask 65 is measured, and an illumination amount of light at each position of the reflection photomask 65 is changed corresponding to the in-plane reflectance distribution. Therefore, exposure at each position on the semiconductor substrate 30 of light reaching the semiconductor substrate 30 after reflected from the reflection photomask 65 becomes uniform. As a result, resist size precision on the semiconductor substrate 30 can be increased. While an example that intensity of light output from the reflection photomask 65 is made uniform is explained above, it is also possible to adjust a light intensity distribution of light incident to the reflection photomask 65 so that the light intensity of light output from the reflection photomask 65 has a desired intensity distribution.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of obtaining exposure correction information comprising:
adjusting intensity of light incident on a photomask so that intensity of light output from the photomask has a desired distribution, based on an output-light ratio as a ratio of the intensity of output light that passes through or is reflected by the photomask to the intensity of the incident light, at each position in a plane of the photomask; and
obtaining the exposure correction information as a distribution of the adjusted intensity of light incident on the photomask.

2. The method according to claim 1, wherein the output-light ratio is a ratio obtained from any one of states of a mask substrate serving as a basis of the photomask, the mask substrate on an entire surface of which a non-patterned predetermined film is formed, and the mask substrate on which a patterned predetermined film is formed.

3. The method according to claim 2, wherein the output-light ratio is obtained using one mask substrate extracted from a plurality of mask substrates manufactured through a same process in a same manufacturing process.

4. The method according to claim 2, wherein the output-light ratio is obtained by averaging output-light ratios of a plurality of mask substrates extracted from a plurality of mask substrates manufactured through a same process in a same manufacturing process.

5. The method according to claim 2, wherein the output-light ratio is obtained using light having an incident-light angle relative to a normal line of a pattern formation plane of the mask substrate within a range of 0 to 20 degrees.

6. The method according to claim 2, wherein the output-light ratio is obtained using polarization light.

7. The method according to claim 1, wherein the exposure correction information is calculated considering a coating variation of resist coated on a substrate to be exposed, in addition to the output-light ratio.

8. The method according to claim 1, wherein the exposure correction information is a distribution of a deviation of an exposure at each position on the photomask from an exposure serving as a basis.

9. The method according to claim 1, wherein the exposure correction information is a distribution on the photomask of incident light, which is adjusted so that intensity of light output from the photomask becomes uniform.

10. A device that obtains exposure correction information, comprising:
an adjusting unit for adjusting intensity of light incident on a photomask so that intensity of light output from the photomask has a desired distribution, based on an output-light ratio as a ratio of the intensity of output light that passes through or is reflected by the photomask to the intensity of the incident light from the light source, at each position in a plane of the photomask; and
an obtaining unit for obtaining the exposure correction information as a distribution of the adjusted intensity of light incident on the photomask.

11. The device that obtains exposure correction information according to claim 10, wherein the output-light ratio is a ratio obtained from any one of states of a mask substrate serving as a basis of the photomask, the mask substrate on an entire surface of which a non-patterned predetermined film is formed, and the mask substrate on which a patterned predetermined film is formed.

12. The device that obtains exposure correction information according to claim 11, wherein the output-light ratio is obtained using one mask substrate extracted from a plurality of mask substrates manufactured through a same process in a same manufacturing process.

13. The device that obtains exposure correction information according to claim 11, wherein the output-light ratio is obtained by averaging output-light ratios of a plurality of mask substrates extracted from a plurality of mask substrates manufactured through a same process in a same manufacturing process.

14. The device that obtains exposure correction information according to claim 11, wherein the output-light ratio is obtained using light having an incident-light angle relative to a normal line of a pattern formation plane of the mask substrate within a range of 0 to 20 degrees.

15. The device that obtains exposure correction information according to claim 11, wherein the output-light ratio is obtained using polarization light.

16. The device that obtains exposure correction information according to claim 10, wherein the exposure correction information is calculated considering a coating variation of resist coated on a substrate to be exposed, in addition to the output-light ratio.

17. The device that obtains exposure correction information according to claim 9, wherein the exposure correction information is a distribution of a deviation of an exposure at each position on the photomask from an exposure serving as a basis.

18. The device that obtains exposure correction information according to claim 10, wherein the exposure correction information is a distribution on the photomask of incident light, which is adjusted so that intensity of light output from the photomask becomes uniform.

19. A method of manufacturing a semiconductor device comprising:
adjusting intensity of light output from a photomask, based on an output-light ratio as a ratio of the intensity of output light that passes through or is reflected by the photomask to the intensity of incident light, at each position in a plane of the photomask; and
exposing a semiconductor substrate through the adjusted intensity of light.

20. The method according to claim 19, wherein the semiconductor substrate is exposed using light, which is adjusted so that intensity of light output from the photomask becomes uniform.
